(19) United States
(12) Patent Application Publication
(10) Pub. No.: US 2008/0150646 A1
(43) Pub. Date: Jun. 26, 2008

(54) VARIABLE RC OSCILLATOR

(75) Inventor: Chun-Hsiung CHEN, Hsinchu (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: HOLTEK SEMICONDUCTOR INC., Hsinchu (TW)

(21) Appl. No.: 11/844,401

(22) Filed: Aug. 24, 2007

(30) Foreign Application Priority Data
Dec. 21, 2006 (TW) 095148296

(51) Int. Cl. H03K 3/02

(52) U.S. Cl. 331/143

(57) ABSTRACT

An RC oscillator is provided. The oscillator includes an RC selecting switch disposed in an input port of the oscillator, a resistor output port, a capacitor output port, at least a resistor switch with a first end connected to the RC selecting switch and a second end floatingly connected to the resistor output port, and at least a capacitor switch with a first end connected to the RC selecting switch and a second end floatingly connected to the capacitor output port. The second ends of the resistor switch and the capacitor switch are selectively connected to the resistor output port and the capacitor output port respectively for providing different combinations of a resistor output value and a capacitor output value.

### FIELD OF THE INVENTION

The present invention relates to a RC oscillator. In particular, the present invention relates to a single-channel variable RC oscillator.

### BACKGROUND OF THE INVENTION

Generally, in order to simplify the design and decrease the cost, the commercial multi-combination RC oscillator with an external resistor or an external capacitor is designed by connecting to a resistor or a capacitor thereto. It means that the resistor or the capacitor in the RC oscillator cannot be switched, only the resistance of the resistor or the capacitance of the capacitor can be chosen.

Please refer to FIG. 1, which is a partial circuit diagram showing a first RC oscillator according to the prior art. In FIG. 1, RC oscillator 10 comprises mainly four capacitors (C0 to C3) and four resistors (R0 to R3). Besides, the selection port of the RC oscillator 10 is set in each resistor output port and each capacitor output port, and the common port is set in the input port (CKIN) of the RC oscillator 10.

Because of the circuit design of connecting to a resistor or a capacitor in the RC oscillator 10 as shown in FIG. 1, the design becomes easier and thus decreases the cost. However, since the numbers of the resistor and the capacitor connected thereto are fixed and unchangeable, a resistor or a capacitor is connected in its specific applied port. If the number of the resistor or the number of the capacitor is not enough, the remnant pin in the other port cannot be adopted and thus becomes useless, which is inconvenient and wasteful.

On the other hand, there is another design for the commercial RC oscillator, in which the resistor connection or the capacitor connection is decided by the user with the internal control of the integrated circuit. In fact, the internal part of the integrated circuit should still be designed as a resistor circuit and a capacitor circuit, which thus increases the cost.

Please refer to FIG. 2, which is a partial circuit diagram showing a second RC oscillator according to the prior art. In FIG. 2, the RC oscillator 20 comprises mainly eight RC ports (RC0 to RC7). A resistor or a capacitor is selected by the user through the control port, and then matched up with a resistor or a capacitor connected to an external circuit.

However, the drawback of the RC oscillator 20 in FIG. 2 lies in that each RC pin must be equipped with switches and controlling circuits additionally, which increases the cost. Moreover, the additional switches will increase the time delay of the oscillating circuit, and will decrease the linearity of the oscillating frequency, which is especially obvious under low-voltage operation.

It is therefore attempted by the applicant to deal with the above situation encountered in the prior art.

### SUMMARY OF THE INVENTION

According to one aspect of the present invention, the variable RC oscillator comprises an RC selecting switch disposed in an input port of the oscillator, a resistor output port, a capacitor output port, at least a resistor switch with a first end connected to the RC selecting switch and a second end floatingly connected to the resistor output port, at least a capacitor switch with a first end connected to the RC selecting switch and a second end floatingly connected to the capacitor output port. The second ends of the resistor switch and the capacitor switch are selectively connected to the resistor output port and the capacitor output port respectively for providing different combinations of a resistor output value and a capacitor output value.

According to another aspect of the present prevention, the oscillator is a single-channel variable RC oscillator.

According to further another aspect of the variable RC oscillator, a selection control of the resistor switch and the capacitor switch electrically connected to the ROUT and COUT, respectively, determined by the RC selecting switch is implemented by an external control of the oscillator.

According to further another aspect of the present invention, the resistor output port and the capacitor output port of the RC oscillator, respectively, are electrically connected to different fixed DC voltage levels and an output port of the oscillator, respectively.

According to further another aspect of the present invention, the variable RC oscillator comprises a plurality of enable switches connected between the RC selecting switch and the resistor switch, and between the RC selecting switch and the capacitor switch, respectively, in order to respond at least one enable signal generated by the RC selecting switch for selectively connecting the resistor switch with the resistor output port and the capacitor switch with the capacitor output port.

According to further another aspect of the present invention, the variable RC oscillator comprises m resistor switches and n capacitor switches, wherein m and n are integers greater than one, and m plus n is equal to a bit number of the oscillator.

According to further another aspect of the present invention, the variable oscillator comprises: (a) an RC selecting switch disposed in an input of the oscillator, (b) a plurality of resistor switches, each of which having a first end connected to the RC selecting switch and a second end floatingly connected to a resistor output of the oscillator, and (c) a plurality of capacitor switches, each of which having a first end connected to the RC selecting switch and a second end floatingly connected to a capacitor output of the oscillator, each of the second ends of the plurality of resistor switches and each of the second ends of the plurality of capacitor switches are selectively connected to the resistor output and the capacitor output, respectively.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a partial circuit diagram showing a first RC oscillator according to the prior art;

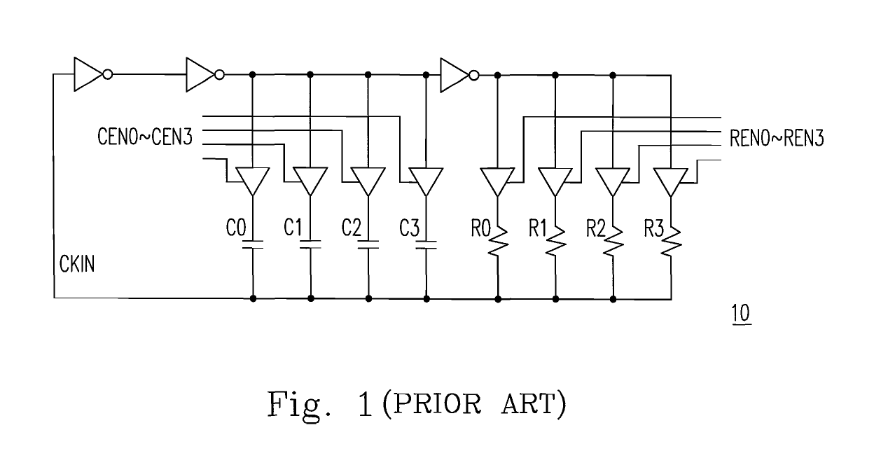

FIG. 2 is a partial circuit diagram showing a second RC oscillator according to the prior art;

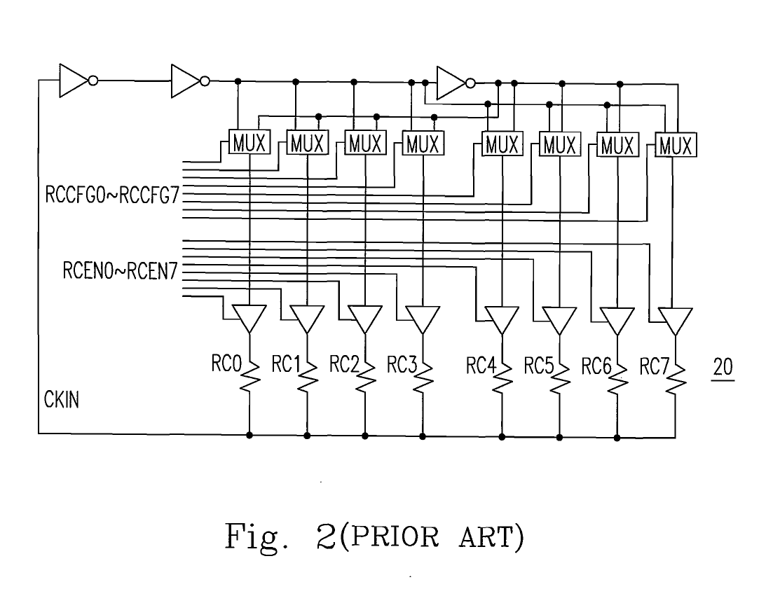

FIG. 3 is a circuit diagram showing a variable RC oscillator in accordance with a preferred embodiment of the present invention;

FIG. 4(a) is a circuit diagram showing a first preferred embodiment of the variable RC oscillator shown in FIG. 3;

FIG. 4(b) is a circuit diagram showing a second preferred embodiment of the variable RC oscillator shown in FIG. 3;

FIG. 5(a) is a circuit diagram showing a single-channel variable RC oscillator in accordance with a preferred embodiment of the present invention; and

FIG. 5(b) is a circuit diagram showing a single-channel variable RC oscillator in accordance with another preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

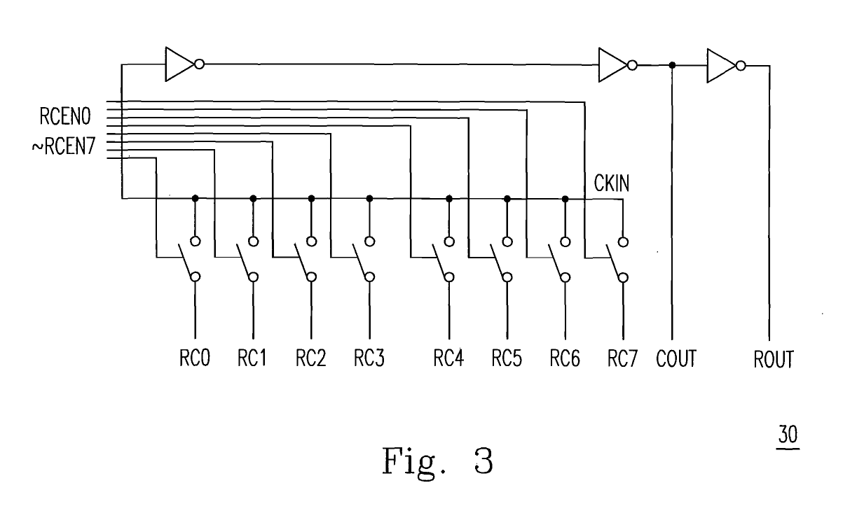

The original principle of the present invention will be described as follows. Please refer to FIG. 3, which is a circuit diagram showing a variable RC oscillator in accordance with a preferred embodiment of the present invention. In FIG. 3, the RC oscillator 30 comprises an RC selecting switch disposed in an input port (CKIN) of the oscillator 30 (in the external part, not shown in the figure), a resistor output port (ROUT), a capacitor output port (COUT), a plurality of resistor switches/capacitor switches (RC0 to RC7). When the switch is a resistor switch, a first end of the resistor switch is connected to the RC selecting switch and a second end of the resistor switch is floatingly connected to the ROUT. When the switch is a capacitor switch, a first end of the capacitor switch is connected to the RC selecting switch and a second end of the capacitor switch is floatingly connected to the COUT.

The present invention is characterized in that the second ends of the resistor switch and the capacitor switch are selectively connected to the ROUT and the COUT respectively with the RC selecting switch, for providing different combinations of a resistor output value and a capacitor value at the resistor output port ROUT and the capacitor output port COUT. Thus a different output is provided at the output port or different fixed DC voltage levels are provided at the output port.

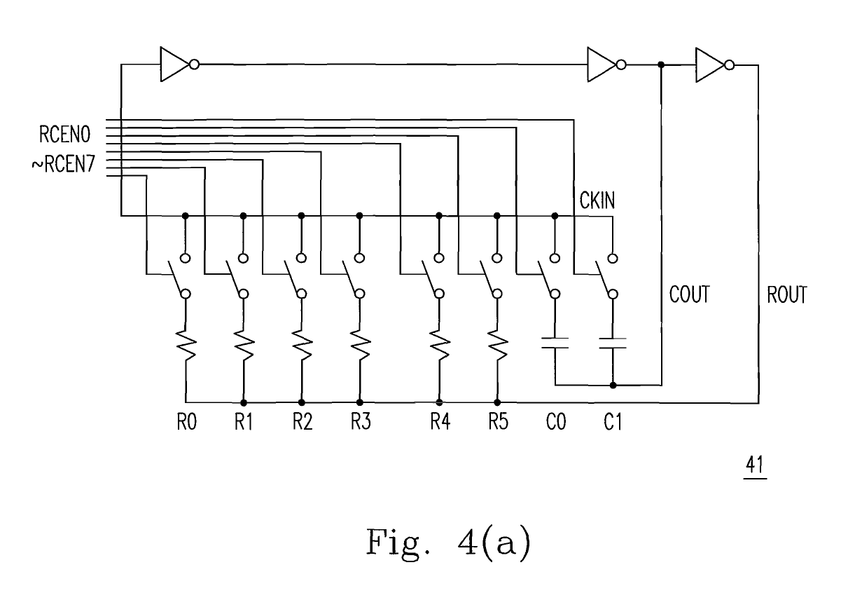

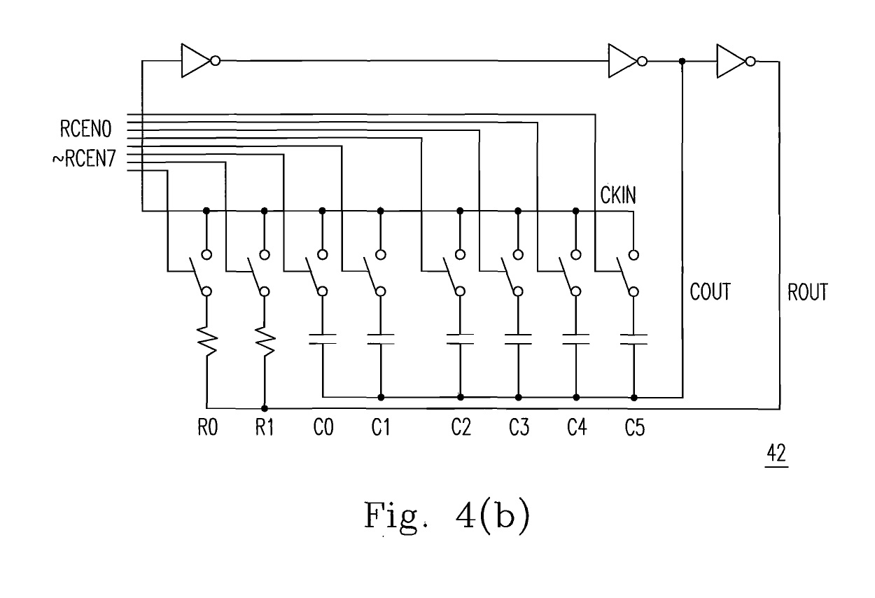

FIG. 4(a) is a circuit diagram showing a preferred embodiment of the variable RC oscillator according to the present invention. In FIG. 4(a), the RC oscillator 41 is an 8-bit oscillator, which comprises six resistor switches (R0 to R5) and two capacitor switches (C0 to C1). For example, for the use of the resistor switch R1, a selection controls the resistor switch R1 to be electrically connected to the resistor output port (ROUT). For the use of the capacitor switch C0, a selection controls the capacitor switch C0 to be electrically connected to the capacitor output port (COUT). Therefore, the pins of RC selecting can be arranged in demand to achieve the function of connection to a resistor or a capacitor randomly.

Therefore, the RC oscillator 41 shown in FIG. 4(a) comprises six resistor switches and two capacitor switches and provides 12 (6×2) combinations of a resistor output value and a capacitor output value on the ROUT and the COUT.

Please refer to FIG. 4(b), which is a circuit diagram showing a second preferred embodiment of the variable RC oscillator according to the present invention. In FIG. 4(b), the RC oscillator 42 is also an 8-bit oscillator, but the difference between this preferred embodiment and the above first embodiment lies in that it comprises two resistor switches (R0 to R1) and six capacitor switches (C0 to C5) and provides 12 (2×6) combinations of a resistor output value and a capacitor output value on the ROUT and the COUT.

In accordance with above two embodiments, it will be readily understood that the variable combinations of each resistor output value and each capacitor output value in the 8-bit RC oscillator can be easily obtained by those skilled in the art. For instance, with four resistor switches and four capacitor switches, 16 (4×4) combinations of a resistor output value and a capacitor output value can be provided at the ROUT and the COUT. With such a set of plurality of resistor switches and such a set of plurality of capacitor switches, 225 (15×15) combinations at most can be obtained.

Although a selection control of the resistor switch and the capacitor switch electrically connected or floatingly connected to the ROUT or COUT is determined by the RC selecting switch, which is implemented by an external control of the oscillator, it can also be implemented by the enable switches connected between each resistor switch and the RC selecting switch, and between each capacitor and the RC selecting switches. With at least one enable signal generated by the RC selecting switch, the connection between the resistor switches and the resistor output port (ROUT), and the connection between the capacitor switches and the capacitor output port (COUT) can be achieved, respectively.

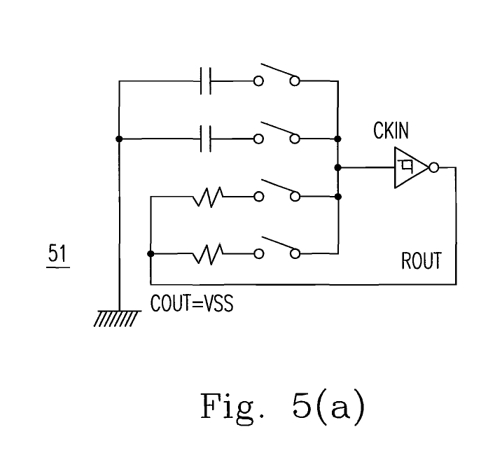

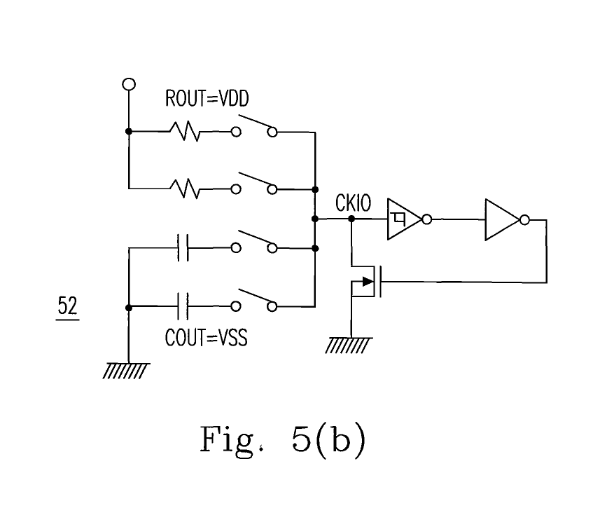

Please refer to FIG. 5(a), which is a circuit diagram showing a single-channel variable RC oscillator in accordance with a preferred embodiment of the present invention. In FIG. 5(a), the single-channel variable RC oscillator 51 comprises two resistor switches and two capacitor switches, wherein the resistor output port (ROUT) is an output port and the capacitor output port (COUT) is a low-voltage port VSS of the single-channel variable RC oscillator 51.

FIG. 5(b) is a circuit diagram showing a single-channel variable RC oscillator in accordance with another preferred embodiment of the present invention. In FIG. 5(b), the single-channel variable RC oscillator 52 also comprises two resistor switches and two capacitor switches, but the difference lies in that the resistor output port (ROUT) is a high-voltage port (VDD) of the single-channel variable RC oscillator 51, and that the capacitor output port (COUT) is a low-voltage port (VSS) of the single-channel variable RC oscillator 52.

The variable RC oscillator provided in the present invention is not only prepared for a single-channel variable RC oscillator, but also prepared for one of the functions of a micro controller unit (MCU). Besides, the numbers of the resistor switches and the capacitor switches depend on the bit numbers of the oscillator. For example, when the oscillator comprises m resistor switches and n capacitor switches and m and n are integers greater than one, then m plus n is equal to the bit number of the oscillator.

In conclusion, a variable RC oscillator with a simple framework provided in the present invention comprises a plurality of combinations of the resistor connection and the capacitor connection. The oscillator connected to a specific resistor or connected to a specific capacitor can be randomly achieved according to user's demand. Moreover, the oscillator thereto can be chosen in demand under the situation for not increasing the numbers of integrated circuits and decreasing the cost. Therefore, the purpose for improving applied diversities of the integrated circuits and the competition of the cost can be achieved.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A variable RC oscillator, comprising:
(a) an RC selecting switch disposed in an input port of the oscillator;
(b) a resistor output port;
(c) a capacitor output port;
(d) at least a resistor switch with a first end connected to the RC selecting switch and a second end floatingly connected to the resistor output port; and
(e) at least a capacitor switch with a first end connected to the RC selecting switch and a second end floatingly connected to the capacitor output port,
wherein the second ends of the resistor switch and the capacitor switch are selectively connected to the resistor output port and the capacitor output port respectively for providing different combinations of a resistor output value and a capacitor output value.

2. The variable RC oscillator according to claim 1, wherein the oscillator is a single-channel variable RC oscillator.

3. The variable RC oscillator according to claim 1, wherein a selection control of the resistor switch and the capacitor switch electrically connected to the ROUT and COUT, respectively, determined by the RC selecting switch is implemented by an external control of the oscillator.

4. The variable RC oscillator according to claim 1, wherein the resistor output port and the capacitor output port are electrically connected to different fixed DC voltage levels, respectively.

5. The variable RC oscillator according to claim 1, wherein the resistor output port and the capacitor output port are electrically connected to an output port of the oscillator.

6. The variable RC oscillator according to claim 1, further comprising:
A plurality of enable switches connected between the RC selecting switch and the resistor switch, and between the RC selecting switch and the capacitor switch, in order to respond at least one enable signal generated by the RC selecting switch for selectively connecting the resistor switch with the resistor output port and the capacitor switch with the capacitor output port.

7. The variable RC oscillator according to claim 1, further comprising m resistor switches and n capacitor switches, wherein m and n are integers greater than one, and m plus n is equal to a bit number of the oscillator.

8. A micro controller unit (MCU), comprising at least a variable RC oscillator according to claim 1.

9. A variable RC oscillator, comprising:
(a) an RC selecting switch disposed in an input of the oscillator;
(b) a plurality of resistor switches, each of which having a first end connected to the RC selecting switch and a second end floatingly connected to a resistor output of the oscillator; and
(c) a plurality of capacitor switches, each of which having a first end connected to the RC selecting switch and a second end floatingly connected to a capacitor output of the oscillator,
wherein each of the second ends of the plurality of resistor switches and each of the second ends of the plurality of capacitor switches are selectively connected to the resistor output and the capacitor output, respectively.
